(19) United States
(12) Patent Application Publication
(10) Pub. No.: US 2021/0407333 A1
(43) Pub. Date: Dec. 30, 2021

(54) DISPLAY PANEL, METHOD FOR MANUFACTURING SAME, AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Ping HE, Wuhan, Hubei (CN); Chengjie JIA, Wuhan, Hubei (CN)

(21) Appl. No.: 16/646,581

(22) PCT Filed: Nov. 15, 2019
(86) PCT No.: PCT/CN2019/118708

§ 371 Date: Mar. 12, 2020

(30) Foreign Application Priority Data
Aug. 19, 2019 (CN) 201910764186.0

(51) Int. Cl. G09F 9/30; H01L 51/56; H01L 51/52

(52) U.S. Cl. CPC G09F 9/301; H01L 2251/5338; H01L 51/52; H01L 51/56

(57) ABSTRACT

Embodiments of the present disclosure provide a display panel, a method for manufacturing a display panel, and a display device. The display panel comprises a display area and a bending area connected to the display area and bent toward a back surface of the display area. The bending area comprises a first bending area and a second bending area comprising a chip-on-film and a flexible printed circuit board. The method for manufacturing a display panel comprises a step of providing the display panel and a step of bending.

### TECHNICAL FIELD

The present disclosure relates to a display technology field, and in particular, to a display panel, a method for manufacturing the display panel, and a display device.

### BACKGROUND

Due to the advantages of being light, thin, bendabable, and foldable, OLED displays can be used in flexible display products, such as foldable mobile phones, smart watches, and in-vehicle display devices.

As shown in FIG. 1 which is a schematic diagram illustrating a foldable display module in a flattened state in prior art, the foldable display module comprises a display area 100 and a bending area 200. The bending area 200 comprises a chip-on-film and a flexible printed circuit board. In the foldable display module, at present, display panels need to reserve a wide border, leading to foldable display products with a wide border after assembled with a cover window, which affects user viewing experience.

### SUMMARY

The present disclosure aims at solving the technical problem of the wide border of the display device with a wide border which affecting user viewing experience.

To achieve the above purpose, an embodiment of the present disclosure provides a display panel comprising a display area, a bending area connected to any one side of the display area and bent toward a back surface of the display area and a chip-on-film connected to the bending area.

In an embodiment, the display area comprises a first side and a second side parallel to each other, and a third side and a fourth side parallel to each other.

In an embodiment, the bending area comprises: a first bending portion bent from the first side toward the back surface of the display area, a second bending portion bent from the second side toward the back surface of the display area, a third bending portion bent from the third side toward the back surface of the display area, and a fourth bending portion bent from the fourth side toward the back surface of the display area.

In an embodiment, the chip-on-film is connected to the fourth bending portion of the bending area.

In an embodiment, a first groove is defined in the first bending portion, and/or a second groove is defined in the second bending portion.

In an embodiment, a shape of the first groove can be trapezoidal, triangular, or rectangular, and/or a shape of the second groove can be trapezoidal, triangular, or rectangular.

To achieve the above purpose, an embodiment of the present disclosure provides a display device comprising the above display panel.

To achieve the above purpose, an embodiment of the present disclosure provides a method for manufacturing a display panel comprising a step of providing the display panel comprising providing the display panel and a step of bending comprising bending a side of the display panel toward a back surface of the display panel.

In an embodiment, the step of bending comprises a first step of bending comprising bending a first side of the display panel toward the back surface of the display panel, a second step of bending comprising bending a second side of the display panel toward the back surface of the display panel, a third step of bending comprising bending a third side of the display panel toward the back surface of the display panel, and a fourth step of bending comprising bending a fourth side of the display panel toward the back surface of the display panel.

In an embodiment, the step of providing the display panel comprises a step of grooving comprising defining grooves in the first side and the third side of the display panel.

The technical effect of the present disclosure is that a whole front surface of the display device is an active display area to achieve a borderless visual effect by bending a part of the display area to the back surface. Defining grooves in a part of the bending portions can relieve the stress when the bending portions are bent, which improves the bendability of the display device.

### BRIEF DESCRIPTION OF DRAWINGS

FIG. 1 is a schematic structure diagram illustrating a display panel before bent in prior art.

FIG. 2 is a schematic structure diagram illustrating a display panel before bent according to a first embodiment of the present disclosure.

FIG. 3 is a front view illustrating a display panel after bent according to the first embodiment of the present disclosure.

FIG. 4 is a schematic structure diagram illustrating a back surface of the display panel after bent according to the first embodiment of the present disclosure.

FIG. 5 is a flow chart illustrating a method for manufacturing a display panel according to an embodiment of the present disclosure.

FIG. 6 is a flow chart illustrating a step of bending according to an embodiment of the present disclosure.

FIG. 7 is a schematic structure diagram illustrating a display panel with rectangular grooves according to a second embodiment of the present disclosure.

FIG. 8 is a schematic structure diagram illustrating a display panel with trapezoidal grooves according to the second embodiment of the present disclosure.

FIG. 9 is a schematic structure diagram illustrating a display panel with triangular grooves according to the second embodiment of the present disclosure.

FIG. 10 is a schematic structure diagram illustrating a display panel with irregularly arranged rectangular grooves according to the second embodiment of the present disclosure.

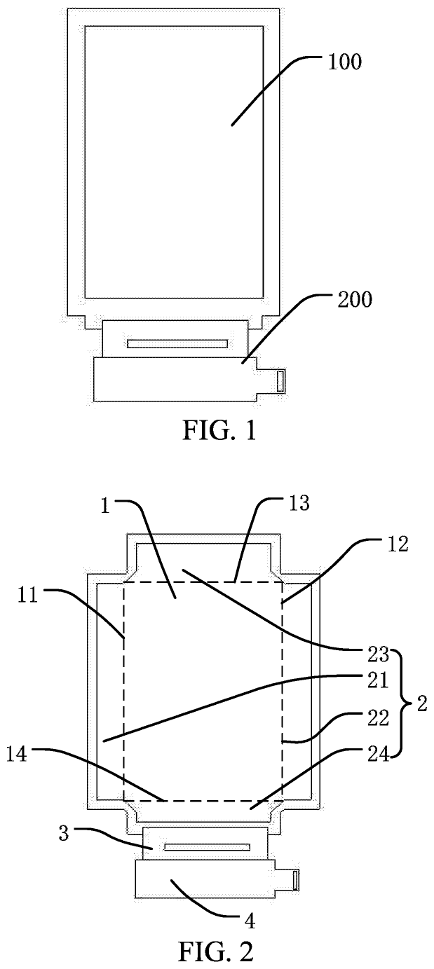

A part of component identifications is shown as follows: display area 100, bending area 200, display area 1, bending area 2, chip-on-film 3, flexible printed circuit board 4, first side 11, second side 12, third side 13, fourth side 14, first bending portion 21, second bending portion 22, third bending portion 23, fourth bending portion 24, first groove 211, and second groove 221.

### DETAILED DESCRIPTION OF PREFERRED EMBODIMENTS

Embodiments of the present disclosure will be described in detail hereinafter with reference to the accompanying drawings, to fully introduce technical content of the present disclosure to a person skilled in the art, to testify that the present disclosure can be implemented as examples, to better clarify technical content of the present disclosure, to assist the person skilled in the art in easier understanding how to implement the present disclosure. However, the present disclosure can be embodied in many different forms, the scope of the present disclosure is not limited to the embodiments mentioned in the text, and the description of the embodiments in the following text is not used to limit the scope of the present disclosure.

Directional terms mentioned in the present disclosure, such as up, down, front, rear, left, right, inside, outside, and side surface, only represent directions in the drawings, used to interpret and describe the present disclosure and not used to limit the protection scope of the present disclosure.

In the accompanying drawings, elements with identical structure are marked with the same reference numerals for convenient understanding and description. The dimension and thickness of each of the elements in the accompanying drawings are arbitrarily shown, and the present disclosure does not define the dimension and thickness of each of the elements.

It will be understood that when an element is referred to as being on another element, it can be directly on the other element, or there may be an intermediate element on which the element is placed, and the intermediate element is placed on the other element. When an element is referred to as being mounted to or connected to another element, either one can be understood as being directly mounted or connected, or via an intermediate element to be indirectly mounted to or connected to the other element.

### The First Embodiment

The embodiment provides a display device. The display device comprises a display panel as shown in FIGS. 2 to 4. The display panel comprises a display area 1, a bending area 2, a chip-on-film 3, and a flexible printed circuit board 4.

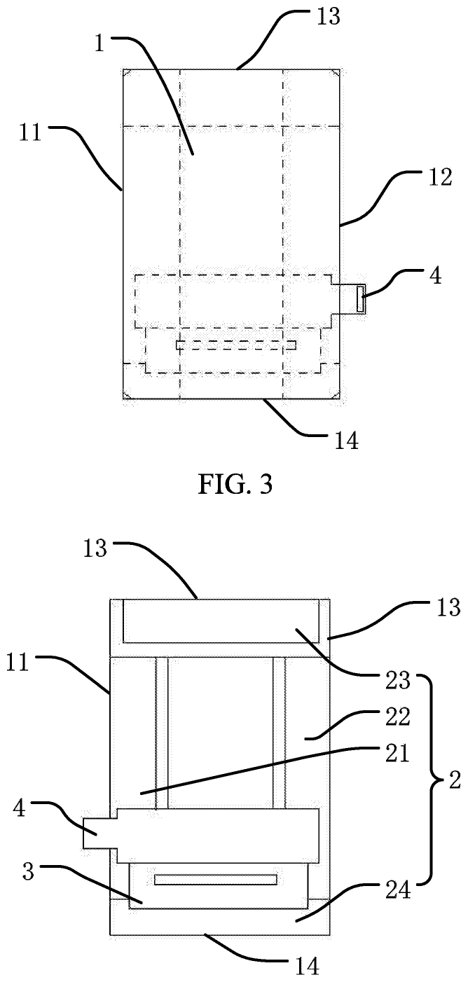

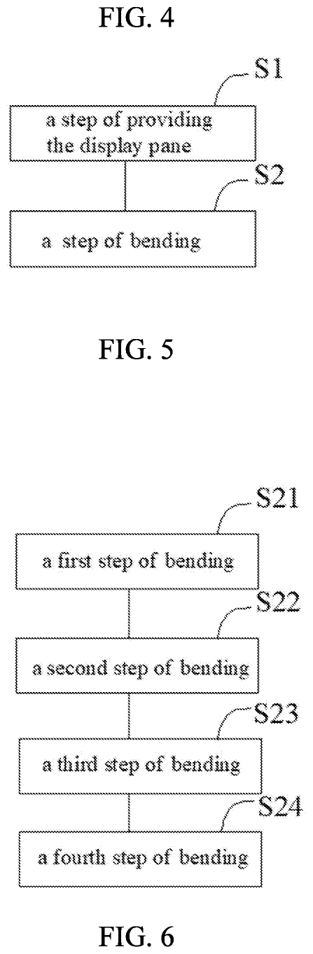

FIG. 2 is a schematic structure diagram illustrating the display panel before bent, FIG. 3 is a front view illustrating the display panel after bent, and FIG. 4 is a schematic structure diagram illustrating a back surface of the display panel after bent.

The display area 1 comprises a first side 11, a third side 13, a second side 12, and a fourth side 14 connected in a head-to-tail manner and arranged clockwise in the embodiment. The first side 11 and the second side 12 are parallel, and the third side 13 and the fourth side 14 are parallel.

The bending area 2 comprises a first bending portion 21, a second bending portion 22, a third bending portion 23, and a fourth bending portion 24.

The first bending portion 21 is bent from the first side 11 toward a back surface of the display area 1, the second bending portion 22 is bent from the second side 12 toward the back surface of the display area 1, the third bending portion 23 is bent from the third side 13 toward the back surface of the display area 1, and the fourth bending portion 24 is bent from the fourth side 14 toward the back surface of the display area 1.

A length of the first bending portion 21 is same as a length of the display area 1, a length of the second bending portion 22 is same as the length of the display area 1, a length of the third bending portion 23 is same as a width of the display area 1, and a length of the fourth bending portion 24 is same as the width of the display area 1.

The display area 1 after bent is an active display area. A part of the display area is bent to the back surface so that a border of the display area is also bent to the back surface, leading to a borderless front surface of the display device, achieving a borderless visual effect, improving the screen ratio of the display device, and further improving users' viewing experience.

Smaller widths of the bending portions are better. In the embodiment, the width of the first bending portion 21 is 0.3 mm to 1 mm, the width of the second bending portion 22 is 0.3 mm to 1 mm, the width of the third bending portion 23 is 0.3 mm to 1 mm, and the width of the fourth bending portion 24 is 0.3 mm to 1 mm.

By adjusting a pixel driving current to zero, any one of the bending portions displays black, that is, the bending portion bent to the back surface of the display area 1 does not display.

During the bending process, a part of any one of the bending portions has a curved surface with a radius of 1.5 mm. The curved surface can be used to display and the display device is commensurate with a display device having a curved screen, such as the existing mobile phone with a curved screen.

The chip-on-film 3 is connected to the fourth bending portion 24. The flexible printed circuit board 4 is disposed on the chip-on-film 3, and the chip-on-film 3 and the flexible printed circuit board 4 are bent together to the back surface of the display area 1 when the fourth bending portion 24 is bent.

A cover window covers the display area 1. The cover window without printing ink is used to improve the overall strength of the display device to make it easier for the display panel to adhere to other components of the display device. The cover window has no visible area (VA) in prior art, leading to the borderless front surface of the display device, achieving a borderless visual effect, improving the screen ratio of the display device, and further improving users' viewing experience.

The technical effect of the display device in the embodiment is that a whole front surface of the display device is the active display area to achieve a borderless visual effect by bending a part of the display area to the back surface.

As shown in FIG. 5, an embodiment further provides a method for manufacturing a display panel comprising steps S1 to S2.

The step S1 is a step of providing the display panel comprising providing the display panel. The display panel comprises a first side, a third side, a second side, and a fourth side connected in a head-to-tail manner. The fourth side is connected to the chip-on-film and the flexible printed circuit board. The display panel is an irregular-shaped structure and a protruding portion is disposed at any one of the sides. Wherein lengths of a first protruding portion at the first side and the first side are same, lengths of a second protruding portion at the second side and the second side are same, lengths of a third protruding portion at the third side and the third side are same, and lengths of a fourth protruding portion at the fourth side and the fourth side are same.

The step S2 is a step of bending comprising bending the protruding portion to form the bending area.

As shown in FIG. 6, the step of bending comprises steps S21 to S24.

The step S21 is a first step of bending comprising bending the first protruding portion of the display panel to fix the first protruding portion to a back portion of the display panel to form a first bending portion.

The step S22 is a second step of bending comprising bending the second protruding portion of the display panel to fix the second protruding portion to the back portion of the display panel to form a second bending portion.

The step S23 is a third step of bending comprising bending the third protruding portion of the display panel to fix the third protruding portion to the back portion of the display panel to form a third bending portion.

The step S24 is a first step of bending comprising bending the fourth protruding portion of the display panel to fix the fourth protruding portion to the back portion of the display panel to form a fourth bending portion. Meanwhile, the chip-on-film and the flexible printed circuit board disposed on the fourth bending portion are bent to the back surface of the display panel. At this time, the display panel not bent is the display area and is used to display.

By adjusting a pixel driving current to zero, any one of the bending portions behind the back surface displays black, that is, the bending portion behind the back surface does not display.

A cover window covers the display area 1. The cover window without printing ink is used to improve the overall strength of the display device to make it easier for the display panel to adhere to other components of the display device. The cover window has no visible area (VA) in prior art, leading to the borderless front surface of the display device, achieving a borderless visual effect, improving the screen ratio of the display device, and further improving users' viewing experience.

The technical effect of the method for manufacturing a display panel in the embodiment is that a whole front surface of the display device is the active display area to achieve a borderless visual effect by bending a part of the display area to the back surface.

### The Second Embodiment

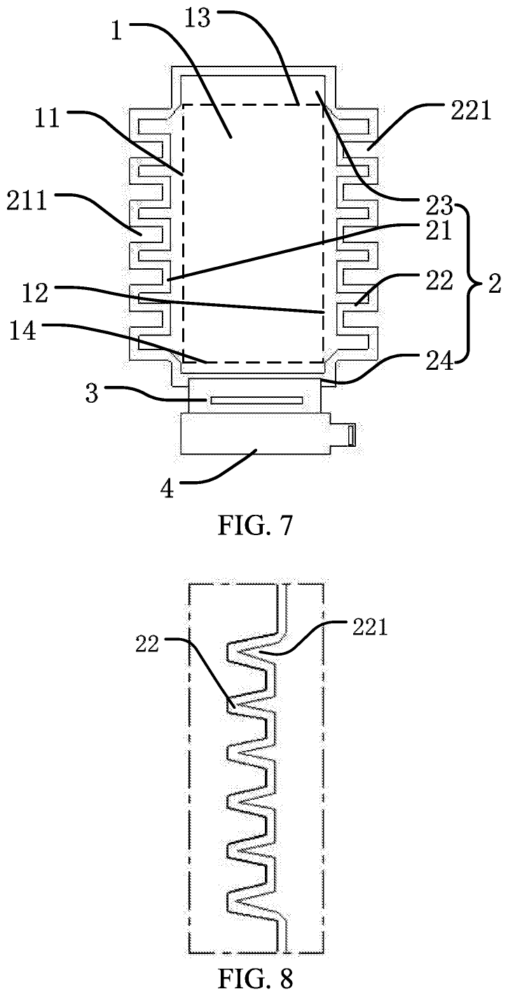

The embodiment provides a display device. The display device comprises a display panel as shown in FIG. 7. The display panel comprises a display area 1, a bending area 2, a chip-on-film 3, and a flexible printed circuit board 4.

The display area 1 comprises a first side 11, a third side 13, a second side 12, and a fourth side 14 connected in a head-to-tail manner and arranged clockwise in the embodiment. The first side 11 and the second side 12 are parallel, and the third side 13 and the fourth side 14 are parallel.

The bending area 2 comprises a first bending portion 21, a second bending portion 22, a third bending portion 23, and a fourth bending portion 24.

The first bending portion 21 is bent from the first side 11 toward a back surface of the display area 1, the second bending portion 22 is bent from the second side 12 toward the back surface of the display area 1, the third bending portion 23 is bent from the third side 13 toward the back surface of the display area 1, and the fourth bending portion 24 is bent from the fourth side 14 toward the back surface of the display area 1.

A length of the first bending portion 21 is same as a length of the display area 1, a length of the second bending portion 22 is same as the length of the display area 1, a length of the third bending portion 23 is same as a width of the display area 1, and a length of the fourth bending portion 24 is same as the width of the display area 1.

First grooves 211 are defined in the first bending portion 21. Shapes of the first grooves 211 are not limited, and are preferably regularly arranged rectangular in the embodiment. Defining the first grooves 211 can relieve the stress when the first bending portion 21 is bent, preventing appearance of breakage and improving the bendability of the display device.

Second grooves 221 are defined in the second bending portion 22. Shapes of the second grooves 221 are not limited, and are preferably regularly arranged rectangular in the embodiment. Defining the second grooves 221 can relieve the stress when the second bending portion 22 is bent, preventing appearance of breakage and improving the bendability of the display device.

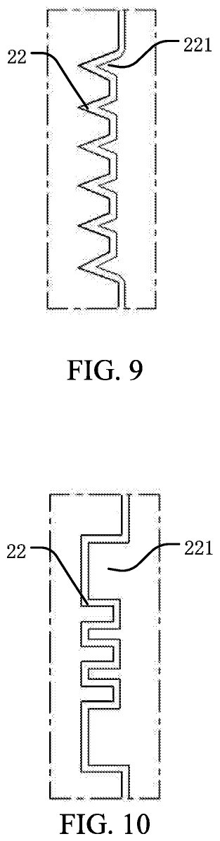

In another embodiments, shapes of the grooves can be trapezoidal (as shown in FIG. 8), triangular (as shown in FIG. 9) or irregularly arranged rectangular (as shown in FIG. 10). Different shapes of the grooves result in different shapes of edges of the display area.

The display area 1 after bent is an active display area. A part of the display area is bent to the back surface so that a border of the display area is also bent to the back surface, leading to a borderless front surface of the display device, achieving a borderless visual effect, improving the screen ratio of the display device, and further improving users' viewing experience.

Smaller widths of the bending portions are better. In the embodiment, the width of the first bending portion 21 is 0.3 mm to 1 mm, the width of the second bending portion 22 is 0.3 mm to 1 mm, the width of the third bending portion 23 is 0.3 mm to 1 mm, and the width of the fourth bending portion 24 is 0.3 mm to 1 mm.

By adjusting a pixel driving current to zero, any one of the bending portions displays black, that is, the bending portion bent to the back surface of the display area 1 does not display.

During the bending process, a part of any one of the bending portions has a curved surface with a radius of 1.5 mm. The curved surface can be used to display and the display device is commensurate with a display device having a curved screen, such as the existing mobile phone with a curved screen.

The chip-on-film 3 is connected to the fourth bending portion 24. The flexible printed circuit board 4 is disposed on the chip-on-film 3, and the chip-on-film 3 and the flexible printed circuit board 4 are bent together to the back surface of the display area 1 when the fourth bending portion 24 is bent.

A cover window covers the display area 1. The cover window without printing ink is used to improve the overall strength of the display device to make it easier for the display panel to adhere to other components of the display device. The cover window has no visible area (VA) in prior art, leading to the borderless front surface of the display device, achieving a borderless visual effect, improving the screen ratio of the display device, and further improving users' viewing experience.

The technical effect of the display device in the embodiment is that a whole front surface of the display device is the active display area to achieve a borderless visual effect by bending a part of the display area to the back surface. Defining grooves in a part of the bending portions can relieve the stress when the bending portions are bent and can improve the bendability of the display device.

As shown in FIG. 5, an embodiment further provides a method for manufacturing a display panel comprising steps S1 to S2.

The step S1 is a step of providing the display panel comprising providing the display panel. The display panel comprises a first side, a third side, a second side, and a fourth side connected in a head-to-tail manner. The fourth side is connected to the chip-on-film and the flexible printed circuit board.

The display panel is an irregular-shaped structure and a protruding portion is disposed at any one of the sides. Wherein lengths of a first protruding portion at the first side and the first side are same, lengths of a second protruding portion at the second side and the second side are same, lengths of a third protruding portion at the third side and the third side are same, and lengths of a fourth protruding portion at the fourth side and the fourth side are same.

The step of providing the display panel further comprises a step of grooving. By the step of grooving, a first groove is defined in the first protruding portion of the display panel and a second groove is defined in the second protruding portion of the display panel. A shape of the first groove can be regularly shaped rectangular, trapezoidal, triangular, or irregularly shaped rectangular, and a shape of the second groove can be regularly arranged rectangular, trapezoidal, triangular, and irregularly shaped rectangular.

The step S2 is a step of bending comprising bending the protruding portion to form the bending area.

As shown in FIG. 6, the step of bending comprises steps S21 to S24.

The step S21 is a first step of bending comprising bending the first protruding portion of the display panel to fix the first protruding portion to a back portion of the display panel to form a first bending portion.

The step S22 is a second step of bending comprising bending the second protruding portion of the display panel to fix the second protruding portion to the back portion of the display panel to form a second bending portion.

The step S23 is a third step of bending comprising bending the third protruding portion of the display panel to fix the third protruding portion to the back portion of the display panel to form a third bending portion.

The step S24 is a first step of bending comprising bending the fourth protruding portion of the display panel to fix the fourth protruding portion to the back portion of the display panel to form a fourth bending portion. Meanwhile, the chip-on-film and the flexible printed circuit board disposed on the fourth bending portion are bent to the back surface of the display panel. At this time, the display panel not bent is the display area and is used to display.

By adjusting a pixel driving current to zero, any one of the bending portions behind the back surface displays black, that is, the bending portion behind the back surface does not display.

A cover window covers the display area 1. The cover window without printing ink is used to improve the overall strength of the display device to make it easier for the display panel to adhere to other components of the display device. The cover window has no visible area (VA) in prior art, leading to the borderless front surface of the display device, achieving a borderless visual effect, improving the screen ratio of the display device and further improving user viewing experience.

The technical effect of the method for manufacturing a display panel in the embodiment is that a whole front surface of the display device is the active display area to achieve a borderless visual effect by bending a part of the display area to the back surface. Defining grooves in a part of the bending portions can relieve the stress when the bending portions are bent and can improve the bendability of the display device.

The descriptions above are just embodiments of the present disclosure. It should be pointed out that, to the general technical personnel in the art, not out of the premise of principle of the present disclosure, some improvement and decoration can be done, these improvements and decoration should also be in the protection scope of the present disclosure.

1. A display panel comprising:
a display area;
a bending area connected to any one side of the display area and bent toward a back surface of the display area; and
a chip-on-film connected to the bending area.

2. The display panel as claimed in claim 1, wherein the display area comprises:
a first side and a second side parallel to each other; and
a third side and a fourth side parallel to each other.

3. The display panel as claimed in claim 2, wherein the bending area comprises:
a first bending portion bent from the first side toward the back surface of the display area;
a second bending portion bent from the second side toward the back surface of the display area;
a third bending portion bent from the third side toward the back surface of the display area; and
a fourth bending portion bent from the fourth side toward the back surface of the display area.

4. The display panel as claimed in claim 3, wherein the chip-on-film is connected to the fourth bending portion of the bending area.

5. The display panel as claimed in claim 3, wherein a first groove is defined in the first bending portion, and/or a second groove is defined in the second bending portion.

6. The display panel as claimed in claim 4, wherein a shape of the first groove can be trapezoidal, triangular, or rectangular, and/or a shape of the second groove can be trapezoidal, triangular, or rectangular.

7. A display device comprising a display panel, wherein the display panel comprises:
a display area;
a bending area connected to any one side of the display area and bent toward a back surface of the display area; and
a chip-on-film connected to the bending area.

8. A method for manufacturing a display panel, wherein the display panel comprises a display area and a bending area connected to any one side of the display area, the method comprises:
a step of providing the display panel comprising providing the display panel; and
a step of bending comprising bending the side of the display panel toward a back surface of the display panel.

9. The method for manufacturing the display panel as claimed in claim 8, wherein the display area comprises a first side and a second side parallel to each other and a third side and a fourth side parallel to each other, the step of bending comprises:
a first step of bending comprising bending the first side of the display panel toward the back surface of the display panel;
a second step of bending comprising bending the second side of the display panel toward the back surface of the display panel;
a third step of bending comprising bending the third side of the display panel toward the back surface of the display panel; and
a fourth step of bending comprising bending the fourth side of the display panel toward the back surface of the display panel.

10. The method for manufacturing the display panel as claimed in claim 9, wherein the step of providing the display panel comprises a step of grooving comprising defining grooves in the first side and the third side of the display panel.

11. The display device as claimed in claim 7, wherein the display area comprises:
a first side and a second side parallel to each other; and
a third side and a fourth side parallel to each other;
wherein the first side is connected between the third side and the fourth side and the second side is connected between the third side and the fourth side.

12. The display device as claimed in claim 11, wherein the bending area comprises:
a first bending portion bent from the first side toward the back surface of the display area;
a second bending portion bent from the second side toward the back surface of the display area;
a third bending portion bent from the third side toward the back surface of the display area; and
a fourth bending portion bent from the fourth side toward the back surface of the display area.

13. The display device as claimed in claim 12, wherein the chip-on-film is connected to the fourth bending portion of the bending area.

14. The display device as claimed in claim 12, wherein a first groove is defined in the first bending portion, and/or a second groove is defined in the second bending portion.

15. The display device as claimed in claim 13, wherein a shape of the first groove can be trapezoidal, triangular or rectangular, and/or a shape of the second groove can be trapezoidal, triangular, or rectangular.

16. The method for manufacturing the display panel as claimed in claim 10, wherein each of shapes of the grooves can be trapezoidal, triangular, or rectangular.
